(19) United States
(12) Patent Application Publication
(10) Pub. No.: US 2011/0194263 A1
(43) Pub. Date: Aug. 11, 2011

(54) SURFACE CONTACT CARD HOLDER FOR ELECTRONIC DEVICE

(75) Inventors: JUN SHEN, Shenzhen City (CN); PING GAO, Shenzhen City (CN); HAI-FENG ZHU, Shenzhen City (CN); QUAN-LONG CHEN, Shenzhen City (CN); XIU-WEN YANG, Shenzhen City (CN)

(73) Assignees: SHENZHEN FUTAIHONG PRECISION INDUSTRY CO., LTD., ShenZhen City (CN); FIH (HONG KONG) LIMITED, Kowloon (HK)

(21) Appl. No.: 12/825,455

(22) Filed: Jun. 29, 2010

(30) Foreign Application Priority Data
Feb. 9, 2010 (CN) 201020302700.3

(51) Int. Cl. H05K 5/02

(52) U.S. Cl. 361/754

(57) ABSTRACT

A holder for a surface contact card includes a housing, a tray and an ejecting mechanism. The housing defines a receiving groove. The tray is slidably received in the receiving groove. The ejecting mechanism is positioned on the housing and automatically ejects the tray from the receiving groove.

### BACKGROUND

1. Technical Field

The present disclosure generally relates to card use in electronic devices, and particularly, to a surface contact card holder for an electronic device.

2. Description of related art

Surface contact cards having special circuits are widely used in portable electronic devices to enhance or specialize the functions of the portable electronic devices. For example, a subscriber identity module (SIM) card in a mobile phone can dedicate the mobile phone's functions to the SIM card owner. By changing SIM cards, a single mobile phone can be used by many different SIM card owners as a personal phone.

Although surface contact card holders may be simple, it can be difficult for the surface contact card to be removed from the surface contact card holder.

Therefore, there is room for improvement within the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the surface contact card holder. Moreover, in the drawings, like reference numerals designate corresponding parts throughout the several views, in which:

FIG. 1 is an isometric view of a surface contact card holder in accordance with an exemplary embodiment;

FIG. 2 is an exploded, isometric view of the surface contact card holder;

FIG. 3 is an enlarged view of the slidable block;

FIG. 4 is an assembly, isometric view of the electronic device;

FIG. 5 is a schematic view of the surface contact card holder with the surface contact card; and

FIG. 6 is an open schematic view of the surface contact card holder showing the surface contact card in place.

### DETAILED DESCRIPTION

The disclosed surface contact card holder can seat surface contact cards such as SIM cards, compact flash cards (CFs), multimedia cards (MMCs), and others. The disclosed electronic device, shown in the exemplary embodiment as a mobile phone, can alternatively be a personal digital assistant (PDA), camera, recorder, or other device, while remaining well within the scope of the disclosure.

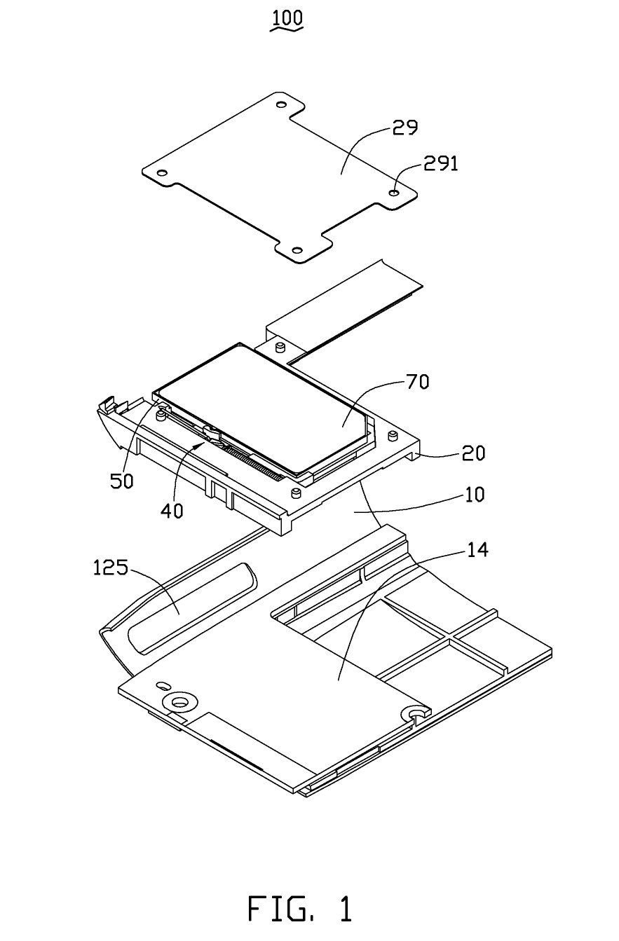

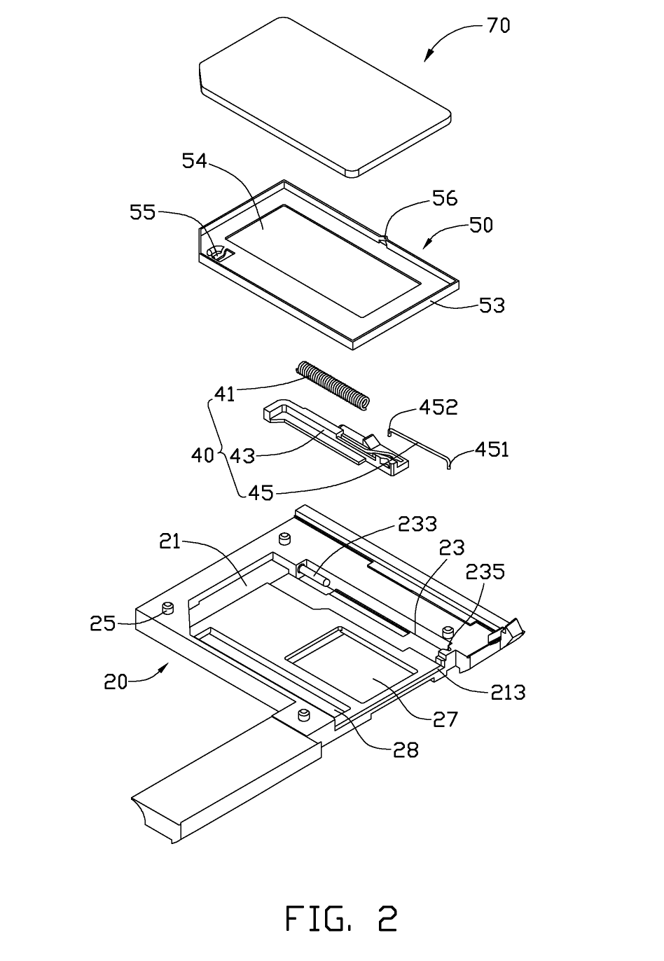

FIGS. 1 and 2 show a surface contact card holder 100 mounted on an electronic device. The surface contact card holder 100 includes a first housing 10, a printed circuited board (PCB) 14, a second housing 20, an ejecting mechanism 40, and a tray 50. The tray 50 is slidably disposed on the second housing 20 to receive a surface contact card 70. The ejecting mechanism 40 provides a force to the tray 50 allowing the tray 50 to slide out from the electronic device.

The first housing 10 and the second housing 20 may be portions of the electronic device. In an exemplary embodiment, the first housing 10 is an outer housing of the electronic device, and the second housing 20 is a middle housing of the electronic device. The PCB 14 may be disposed between the first housing 10 and the second housing 20. The first housing 10 defines a button hole 125. The second housing 20 defines a receiving groove 21 and a slot 23. The receiving groove 21 is configured to receive the tray 50, and includes an entrance 213 allowing the tray 50 to enter within the entrance 213. The slot 23 is at one side of the receiving groove 21, and communicates with the receiving groove 21. A first post 233 is disposed at one end of the slot 23, and a notch 235 is defined at the other side of the slot 23. The bottom surface of the receiving groove 21 defines an opening 27 and a hole 28. The opening 27 allows the surface contact card 70 in the tray 50 to be electronically connected to the PCB 14. Pins 25 are positioned around the receiving groove 21. A cover 29 is used for covering the receiving groove 21, and defines pin holes 291 corresponding to the pins 25.

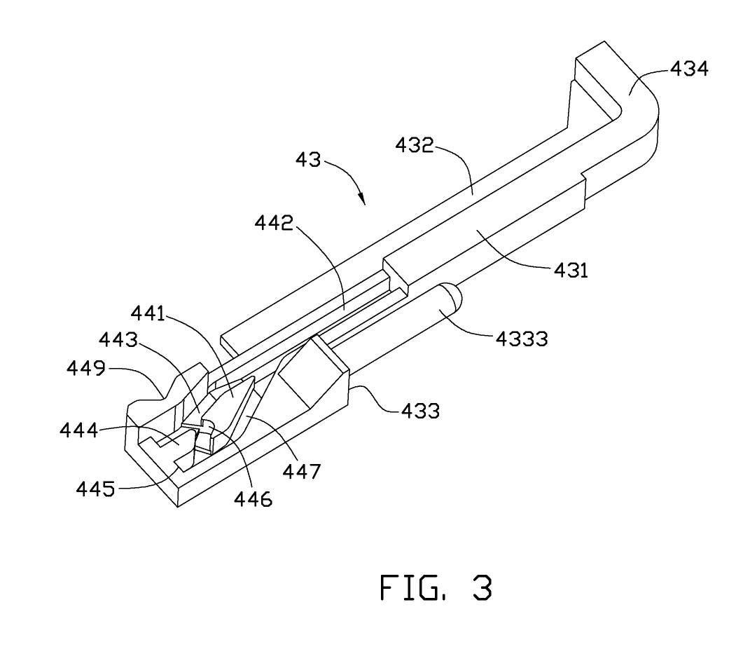

The ejecting mechanism 40 includes an elastic member 41, a slidable block 43 and a connecting rod 45. The elastic member 41 may be a substantially helical spring, and one end of the elastic member 41 is placed around the first post 233. Referring to FIG. 3, the slidable block 43 is shorter than the slot 23, and may allow the slidable block 43 to slide in the slot 23. The slidable block 43 includes a base plate 431 defining a chamber 432 communicating with one side thereof. A resisting end 434 is formed at one end of the chamber 432. A stopper wall 433 extends from the other side of the base plate 431. A second post 4333 extends from the stopper wall 433. The base plate 431 defines a main passage 442, a first branch passage 443 and a second branch passage 447. A guiding projection 441 and an extending projection 444 are formed between the first branch passage 443 and the second branch passage 447. The guiding projection 441 defines a recess 446 opposite to one end of the extending projection 444. A latching end 445 is formed at one end of the second passage 447. A depression 449 is defined in the base plate 431. The connecting rod 45 includes a first bendable hook 451 and a second bendable hook 452 at two ends thereof. The first bendable hook 451 is latched in the notch 235, and the second bendable hook 452 is slidably received in the main passage 442 and the second branch passage 447.

The tray 50 defines a channel 54 for receiving the surface contact card 70. A button 53 is formed at one end of the tray 50. A guiding member 55 is formed at a bottom of the tray 50 for being slidably received in the hole 28. A protrusion 56 protrudes from one side of the tray 50 for engaging in the depression 449.

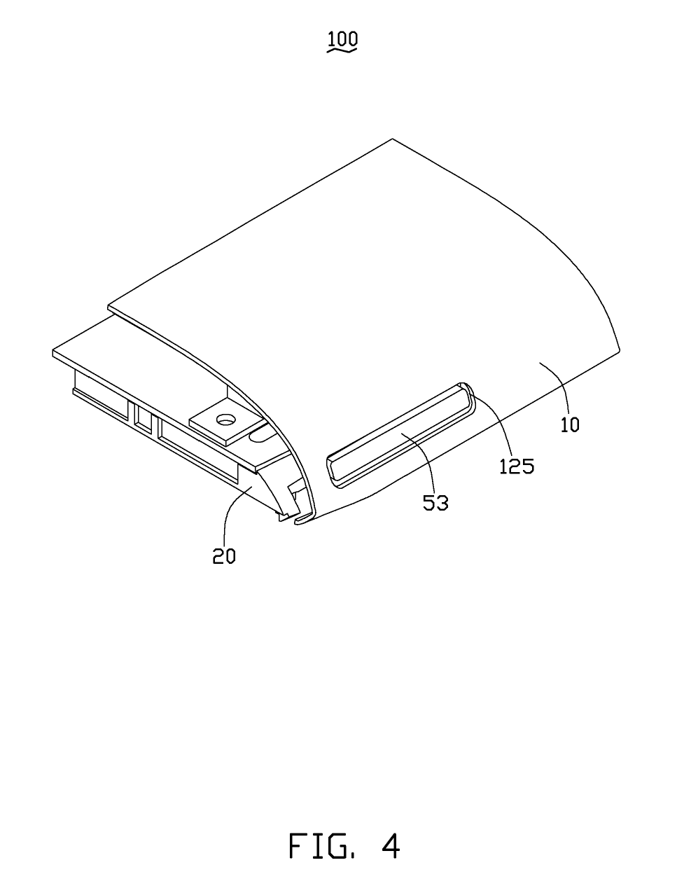

During assembly, the slidable block 43 is received in the receiving groove 21 and the slot 23. The elastic member 41 is respectively placed around the first post 233 and the second post 4333. The surface contact card 70 is inserted into the tray 50. Then, the tray 50 is slidably received in the receiving groove 21. Referring to FIG. 4, one end of the tray 50 abuts the resisting end 434. The button 53 is exposed from the entrance 213. The protrusion 56 is latched in the depression 449 of the slidable block 43. The first bendable hook 451 is latched in the notch 235, and the second bendable hook 452 is latched in the recess 446. The elastic member 41 is in a relaxed state. The second housing 20 with the tray 50 is assembled to the first housing 10. The button 53 is exposed from the button hole 125 of the first housing 10. The surface contact card 70 is thereby held steadily in the first housing 10 and the second housing 20.

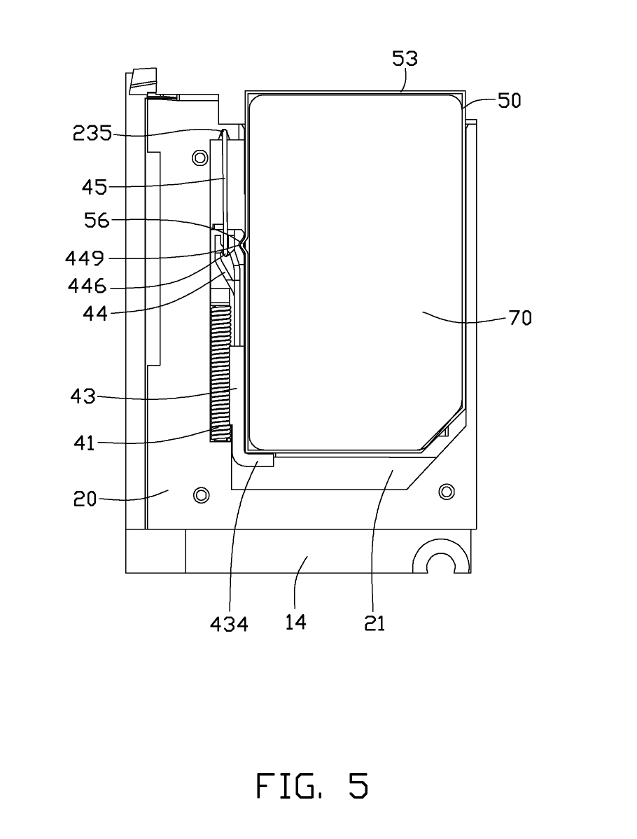

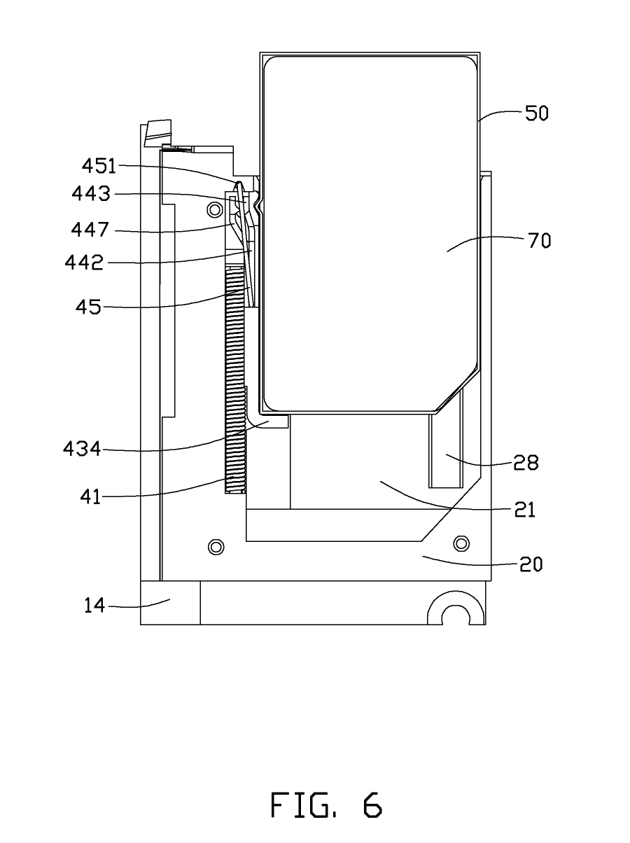

Referring to FIGS. 5 and 6, to remove the surface contact card 70, the button 53 is pushed to cause the tray 50 to slide. Since the protrusion 56 of the tray 50 is latched in the depression 449, the slidable block 43 is forced to slide with the tray 50. The elastic member 41 is compressed, and the second hook 452 is unlocked from the recess 446 to slide to the latching end 445. Then, the button 53 is released, and the expansion force from the elastic member 41 causes the slidable block 43 to slide in the slot 23 until the tray 50 is automatically slid out from the receiving groove 21. The second hook 452 slides in the main passage 442. Next, the tray 50 is drawn out under force to allow the protrusion 56 to separate from the depression 449. The surface contact card 70 is easily removed from the tray 50.

As described above, the exemplary embodiment provides a surface contact card holder for portable electronic devices, such as mobile phones. The surface contact card holder can be easily opened and is more user-friendly.

It is believed that the present embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A holder for a surface contact card, comprising:
a housing defining a receiving groove;
a tray slidably received in the receiving groove;
an ejecting mechanism positioned on the housing and automatically ejecting the tray from the receiving groove.

2. The holder as claimed in claim 1, wherein the ejecting mechanism includes a slidable block and a connecting rod, one end of the connecting rod is fixed to the housing, and the other end of the connecting rod is slidably received in the slidable block

3. The holder as claimed in claim 2, wherein the slidable block includes a base plate defining a main passage, a first branch passage and a second branch passage, a guiding projection and an extending projection are formed between the first branch passage and the second branch passage.

4. The holder as claimed in claim 3, wherein the guiding projection defines a recess opposite to one end of the extending projection to releasably lock one end of the connecting rod.

5. The holder as claimed in claim 4, wherein the base plate defines a chamber communicating with one side thereof, a resisting end is formed at one end of the chamber.

6. The holder as claimed in claim 4, wherein the housing forms a first post, a stopper wall extends from the other side of the base plate, a second post extends from the stopper wall, an elastic member is place around the first post and the second post.

7. The holder as claimed in claim 1, wherein a depression is defined in the base plate, the tray forms a protrusion being received in the depression.

8. The holder as claimed in claim 7, wherein the connecting rod includes a first bendable hook and a second bendable hook at two ends thereof, the first bendable hook is latched in the notch, and the second bendable hook is slidably in the first passage and the second passage.

9. The holder as claimed in claim 8, wherein the second housing defines a slot, the slot is at one side of the receiving groove, and communicates with the receiving groove, a first post is disposed at one end of the slot, and a notch is defined at the other side of the slot.

10. A portable electronic device comprising a holder for a surface contact card, the holder mounted on the portable electronic device and comprising:
a first housing defining a button hole;
a second housing defining a receiving groove; and
a tray configured for carrying a surface contact card therein, the tray includes a button received in the button hole;
an ejecting mechanism positioned between the tray and the second housing, the ejecting mechanism proving a force to the tray to eject from the receiving groove;
wherein the tray slidably engages in the receiving groove allowing insertion and removal of the surface contact card from inside the first housing and the second housing.

11. The portable electronic device as claimed in claim 10, wherein the ejecting mechanism includes a slidable block and a connecting rod, one end of the connecting rod is fixed to the housing, and the other end of the connecting rod is slidably received in the slidable block

12. The portable electronic device as claimed in claim 11, wherein the slidable block includes a base plate defining a main passage, a first branch passage and a second branch passage, a guiding projection and an extending projection are formed between the first branch passage and the second branch passage.

13. The portable electronic device as claimed in claim 12, wherein the guiding projection defines a recess opposite to one end of the extending projection to releasably lock one end of the connecting rod.
